(19) United States
(12) Patent Application Publication
(10) Pub. No.: US 2004/0232408 A1
(43) Pub. Date: Nov. 25, 2004

(54) Bilayer high dielectric constant gate insulator

(76) Inventors: Alan J. Heeger, Santa Barbara, CA (US); Daniel Moses, Santa Barbara, CA (US); Guangming Wang, Goleta, CA (US)

Correspondence Address: FULBRIGHT & JAWORSKI L.L.P., Robert Berliner, Twenty-Ninth Floor, 865 South Figueroa, Los Angeles, CA, 90017-2571, US

(21) Appl. No.: 10/442,615

(22) Filed: May 21, 2003

(51) Int. Cl. H01L 35/24

(52) U.S. Cl. 257/40

(57) ABSTRACT

An improved semiconducting polymer field effect transistor is provided having a higher density of carriers in the channel while maintaining high carrier mobility by applying a passivating thin layer of low dielectric constant insulator in contact with and between the layer of high dielectric constant gate insulator and semiconducting polymer.

### FIELD OF THE INVENTION

The field of the invention is semiconducting polymer field effect transistors.

### BACKGROUND OF THE INVENTION

Field-effect transistors (FETs) fabricated with semiconducting polymers offer the promise of “plastic” electronic circuits. The ability to process semiconducting polymers from solution implies low cost manufacturing; however, the low mobilities obtained with these disordered materials limit the range of potential applications. The current that can be switched by an FET is proportional to the product of the number of field-induced carriers per unit area in the channel, N_{c}, times the carrier mobility, μ. In the linear range (|V_{DS}|<|V_{GS}|, where V_{DS} is the source-drain voltage and V_{GS} is the gate-source voltage), N_{c} is approximately constant in the channel and given by:

N_{c}=(k∈ₒ/ed)V_{GS} (1)

where (k∈ₒ) is the dielectric constant of the gate insulator (thickness d), and e is the electron charge. Thus, the use of high dielectric constant (“high k”) materials for the gate insulator can at least partially compensate for the relatively low mobilities of polymer semiconductors. Moreover, with higher dielectric constant gate insulators, the higher charge density causes traps to be filled at lower gate potentials. Consequently, the use of high k gate insulators in polymer FETs might be expected to enable device operation at low drive voltages with good current-voltage characteristics.

Since, however, the field-induced carriers are confined to a very thin region close to the interface of the insulator and the organic semiconductor [A. Dodabalapur, L. Torsi, H. E. Katz, Science, 268 (1995) 270], the nature of that interface is critical. Particularly with a high dielectric constant gate insulator, disorder and surface roughness can reduce the mobility and even lead to localization of the carriers.

Relatively little has been done with high dielectric constant gate insulators in organic FETs. [J. Veres, s. D. Ogier, S. W. Leeming, D. C. Cupertino, Adv. Funct. Mater., 13 (2003) 199]. Although high dielectric constant TiO₂ has been used in inorganic FETs [F. Nihey, H. Hongo, M. Yudasaka, and S. Iijimea, Jpn. J. Appl. Phys. 41 (2002) L1049; S. A. Campbell, D. C. Gilmer, X. Wang, M. Hsieh, H. Kim, W. L. Gladfelter, and J. Yan, IEEE Trans. Electron. Devces, 44 (1997) 104.], it has never been utilized as the gate insulator in organic FETs.

Semiconducting polymers such as the soluble derivatives of polythiophene, the soluble derivatives of poly(phenylene vinylene) and the soluble derivatives of polyfluorene have been used to fabricate field effect transistors. In particular regio-regular poly(3hexylthiophene), RR-P3HT, has been broadly used as the active semiconductor in FETs. Thin films of RR-P3HT can be deposited by a variety of methods, including spin casting [H. Sirringhaus, N. Tessler, R. H. Friend, Science, 280(1998)1741], drop casting [Z. Bao, A. Dodabalapur, and A. J. Lovinger, Appl. Phys. Lett., 69 (26) 4108], printing [Z. Bao, Y. Feng, A. Dodabalapur, V. R. Raju, and A. J. Lovinger, Chem. Mater. 9 (1997) 1299], Langmuir-Blodgett deposition [G. Xu, Z. Bao, and J. T. Groves, Langmuir, 16 (2000) 1834], and by dip coating [G. M. Wang, J. Swensen, D. Moses, A. J. Heeger, J. Appl. Phys. (In press)]. The ordered microcrystalline lamellar structure enables relatively high field-effect mobilities (μ≈0.1 cm²/Vs) [Z. Bao, A. Dodabalapur, and A. J. Lovinger, Appl. Phys. Lett., 69 (26) 4108; H. Sirringhaus, P. J. Brown, R. H. Friend, M. M. Nielsen, K. Bechgaard, B. M. W. Langeveld-Voss, A. J. H. Spiering, R. A. J. Janssen, E. W. Meijer, P. Herwig, and D. M. de Leeuw, Nature 410 (1999) 685]. Dip-coating the RR-P3HT leads to improved structural order and the highest reported hole mobility, μ=0.2 cm²/Vs [G. M. Wang, J. Swensen, D. Moses, A. J. Heeger, J. Appl. Phys. (In press)]. Semiconducting poly(9,9-dioctylfluorene-co-bithiophene), a co-polymer of polyfluorene and polythiophene has also been used as the semiconductor in polymer FETs [N. Stutzman, R. H. Friend and H. Sirringhaus, Science, 299, 1881 (2003 and references therein].

### SUMMARY OF THE INVENTION

It is an object of this invention to provide a structure for FETs fabricated with a semiconducting polymer overlying the high k gate insulator (“semiconducting polymer FET”) that will overcome the limitations associated with the relatively low mobilities of semiconducting polymers. In accordance with the invention, an improved semiconducting polymer FET is provided having a higher density of carriers in the channel while maintaining high carrier mobility by applying a passivating thin layer of low dielectric constant insulator in contact with and between the layer of high k gate insulator and semiconducting polymer.

The use of high k gate insulators in polymer field effect transistors (FETs) leads to device operation at low drive voltages with good current-voltage characteristics. Although the addition of a thin SiO₂ overlayer reduces the effective dielectric constant, the overlayer passivates the surface of the high k gate insulator and thereby causes improved mobilities and improved on/off ratios. Thus, the use of a high k bilayer gate insulator in FETs fabricated from semiconducting polymers improves the polymer FET performance and at least partially compensates for the relatively low mobilities of polymer semiconductors to enable the polymer-based FET to switch relatively large currents.

### BRIEF DESCRIPTION OF THE DRAWINGS

For a more complete understanding of the present invention, reference is now made to the following descriptions taken in conjunction with the accompanying drawing, in which:

FIG. 1 shows schematic diagrams of FET configurations (a) without and (b) with a SiO₂ overlayer on the high dielectric constant gate insulator;

FIG. 2 depicts (a) a “top contact” FET structure and (b) a “bottom contact FET structure;

FIG. 3 depicts leakage current as a function of the applied electric field for TiO₂ and TiO2 with a thin overlayer of SiO₂.;

FIG. 4 depicts (a) a linear plot and (b) semilog plot of I_{DS} vs V_{DS} at various V_{GS} for RR-P3HT FETs with TiO₂ (97 nm) as the gate dielectric, and (c) a linear plot of I_{DS}^{1/2} vs V_{GS};

FIG. 5 depicts AFM images of surfaces (a) TiO₂ film and TiO₂ films with (b) 3 nm thick SiO₂ overlayer and (c) 17 nm thick SiO₂ overlayer;

FIG. 6 depicts (a) a linear plot and (b) semilog plot of I_{DS} vs V_{DS} at various V_{GS} for RR-P3HT FETs using TiO₂ (97 nm) with a SiO₂ overlayer (3 nm) as the gate insulator, and (c) a linear plot of I_{DS}^{1/2} vs V_{GS}.; and

FIG. 7 depicts (a) a linear plot and (b) semilog plot of I_{DS} vs V_{DS} at various V_{GS} for RR-P3HT FETs using TiO₂ (97 nm) with a SiO₂ overlayer (17 nm) as the gate insulator, and (c) a linear I_{DS}^{1/2} vs V_{GS}.

### DETAILED DESCRIPTION OF THE INVENTION

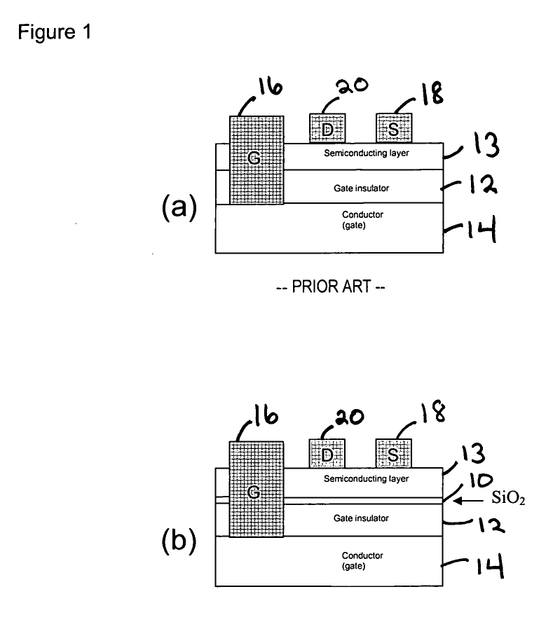

The structure of an FET comprising a bilayer high permittivity gate dielectric is illustrated in FIG. 1. FIG. 1(a) shows an FET without a passivating layer and in FIG. 1(b) with a passivating SiO₂ overlayer 10 on the high dielectric constant gate insulator 12. The FET is a semiconducting polymer FET, but for simplicity of illustration, neither the semiconducting polymer layer nor the substrate is shown in FIG. 1.

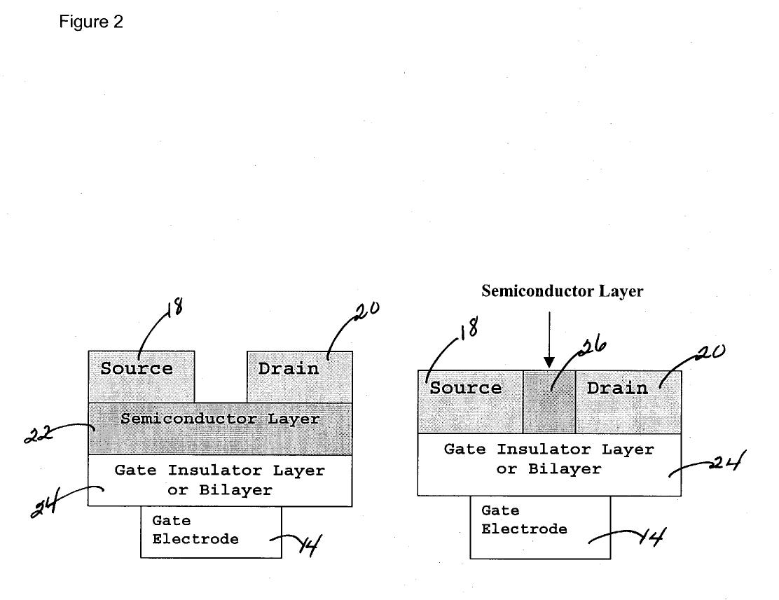

The conductor (gate) 14 can be a thin conducting metallic film, such as gold, silver, aluminium and the like deposited onto a suitable substrate (glass, plastic etc). Alternatively, the gate 14 can be a thin film of conducting polymer such as polyaniline, PANI, or poly(ethylene dioxythiophene), PEDOT and the like deposited onto a suitable substrate (glass, plastic etc). The contact 16, denoted as G in FIG. 1, is also made of conducting material that makes low resistance contacts to the gate 14. The source 18 and the drain 20, denoted respectively as S and D in FIG. 1, are each also made of conducting material that makes low resistance contacts in FIG. 1(a) to the gate insulator 12 and in FIG. 1(b) to the passivating layer 10, either via the semiconducting polymer layer or directly on the bilayer, as will be shown in more detail in FIG. 2. Doped silicon wafers can be used as both the substrate and the gate; e.g. n-type doped or p-type doped to sufficiently high levels to be conducting can serve as the gate for the FET.

In FIG. 1a, the gate insulator 12 is shown as a single layer. In the context of this invention, that single layer is a high dielectric constant insulator, defined for purposes of this invention as having a dielectric constant greater than 40. Examples include, but are not limited to insulating oxides such as alumina, Al₂O₃ and titania, TiO₂. Higher dielectric constant insulators are known and can be used for the gate insulator layer. The principal requirements are that the resulting film have low leakage current and a relatively smooth surface. The latter requirement arises since the field induced electrons in the channel of the FET device are confined to a region of only a few monolayers above the interface between the gate insulator and the semiconducting polymer. Consequently, sharp features in the surface of the high dielectric constant insulator will lead to variations in the local field; such variations in the local field will limit the electronic transport by scattering and can even cause the formation of traps for carriers and carrier localization.

In FIG. 1b, the gate insulator 12 is shown as a bilayer. In the context of this invention, the bilayer comprises a high dielectric constant insulator 12 with a thin overlayer 10 of low dielectric constant, defined for purposes of this invention as having a dielectric constant of less than k=4, exemplified by SiO₂. The thin SiO₂overlayer 10 passivates the surface of the high dielectric constant insulator 12 resulting in improved performance of the FET device with higher currents at lower values of both the source-drain voltage and the gate voltage.

The semiconducting polymer is applied onto the gate insulator by any of a variety of methods. Since the ability to process semiconducting polymers from solution implies low cost manufacturing, application of the semiconducting polymer from solution is preferred. Thin films of semiconducting polymers can be deposited by a variety of methods, including spin casting [H. Sirringhaus, N. Tessler, R. H. Friend, Science, 280(1998)1741.], drop casting [Z. Bao, A. Dodabalapur, and A. J. Lovinger, Appl. Phys. Lett., 69 (26) 4108], printing [Z. Bao, Y. Feng, A. Dodabalapur, V. R. Raju, and A. J. Lovinger, Chem. Mater. 9 (1997) 1299], Langmuir-Blodgett deposition [G. Xu, Z. Bao, and J. T. Groves, Langmuir, 16 (2000) 1834], and by dip coating [G. M. Wang, J. Swensen, D. Moses, A. J. Heeger, J. Appl. Phys. (In press)]. With regio-regular poly(3-hexylthipohene) as the semiconducting polymer, dip-coating leads to improved structural order and the highest reported hole mobility, μ=0.2 cm²/Vs [G. M. Wang, J. Swensen, D. Moses, A. J. Heeger, J. Appl. Phys. (In press)].

An FET with a bilayer high dielectric constant gate insulator of the present invention is described in greater detail in FIG. 2. FIG. 2a shows a “top contact” configuration in which the source and drain electrodes 18 and 20 are deposited directly onto a semiconducting polymer layer 22 that overlies a bilayer gate insulator 24. The bilayer gate insulator 24 is the combination formed of the high dielectric constant gate insulator 12 and the passivating low dielectric constant, e.g., SiO₂, overlayer 10 of FIG. 1(b). FIG. 2b shows a “bottom contact” configuration in which the source and drain electrodes 18 and 20 are deposited directly onto the onto the bilayer gate insulator 24 and are separated by a semiconducting polymer layer 26 which overlies the bilayer gate insulator 24. In FIGS. 2a and 2b, the gate electrode is deposited on or doped directly into the substrate (not shown).

The FET can be fabricated on a variety of substrates, including for example, single crystal substrates, glass substrates, plastic substrates and ceramic substrates. The principal requirement is that the substrate must have a smooth surface and that it be dimensionally stable. Plastic substrates offer the special advantage of flexibility. Although preferred, plastic substrates often suffer from surface roughness and dimensional changes with increased temperature.

The “bottom contact” configuration of FIG. 2(b) is preferred. Bottom-contact structures, processed with standard photolithographic methods offer an important advantage; the sensitive organic thin films are deposited after preparing the source and drain contacts thereby minimizing any damage to or contamination of the active semiconducting layer during device fabrication. However, the use of the bilayer gate insulator is an advantage for the “top contact” configuration as well; i.e. with the source and drain contacts deposited on top of the semiconducting polymer, as shown in FIG. 2b.

In a preferred embodiment, the high dielectric constant insulator has low leakage current; less than 10⁻⁵ A/cm². Lower leakage currents are even more preferred. In another preferred embodiment, the high dielectric constant insulator has high breakdown field, greater than 1 MV/cm. Higher breakdown fields are even more preferred.

In a specific embodiment, the high dielectric constant gate insulator is made with TiO₂ with dielectric constant greater than 40. Materials with still higher dielectric constants are even more preferred.

In a preferred embodiment, the semiconducting polymer layer is deposited from solution. Although a variety of methods for depositing the film are known, such as, for example, spin-casting, dip-coating drop casting and the like, the method that yields the highest carrier mobility is most preferred.

Preferred substrates are glass, doped Si or plastic. Although preferred, plastic substrates often suffer from surface roughness and dimensional changes with increased temperature.

As demonstrated in the Examples, the use of high k gate insulators (e.g. TiO₂ with k=41) in polymer FETs leads to device operation at low drive voltages (operation at 5 V or less) with good current-voltage characteristics. Although the addition of a thin SiO₂ overlayer reduces the effective dielectric constant, the overlayer passivates the TiO₂ surface and yields relatively high mobilities (5×10⁻² cm²/Vs), relatively high on/off ratios (6×10⁴) and source-drain currents of 40 μA (at V_{DS}=10V and V_{GS}=−10 V with L=5 μm and W=1000 μm). Thus, we have demonstrated that gate insulators comprising a high dielectric constant material with a thin SiO₂ overlayer can compensate for the relatively low mobilities of polymer semiconductors and enable the polymer-based FET to switch relatively large currents.

The following general methods and specific examples are presented to illustrate the invention and are not to be considered as limitations thereon.

### EXAMPLE 1

### Lower Leakage Current/Higher Breakdown Voltage with SiO₂ Overlayer

TiO₂ films were deposited onto the N⁺⁺ Si wafers (0.001-0.01 Ω-cm) using a wide-area RF biased, Pulse DC linear scanning magnetron physical vapor deposition (PVD) process developed by Symmorphix in Sunnyvale, Calif. [Hongmei Zhang and Ernest Demaray, Proceedings for 23^{rd} Capacitor and Resistor Technology Symposium, pp124-126.]. For the films used in these experiments, the TiO₂ film deposition power was 7 KW, the pulsed DC frequency was 200 KHz, the oxygen partial pressure was at 60%, and the total pressure was approximately 8 m Torr. Substrate bias power was kept at 300 W. The process provides a dense TiO₂ film with very low extinction, high dielectric strength and high k. The 94 nm thick Al₂O₃ films were deposited using similar hardware. The Al₂O₃ film deposition power was 5.5 KW, the DC pulse frequency was 200 KHz (with a 2.2 us reverse time), the oxygen partial pressure of 70%, and the total pressure inside the chamber was approximately 5 mTorr. To achieve the high breakdown voltage, the substrate bias power was 400 W. The wafers were annealed at 750° C. in Argon for 1 hour.

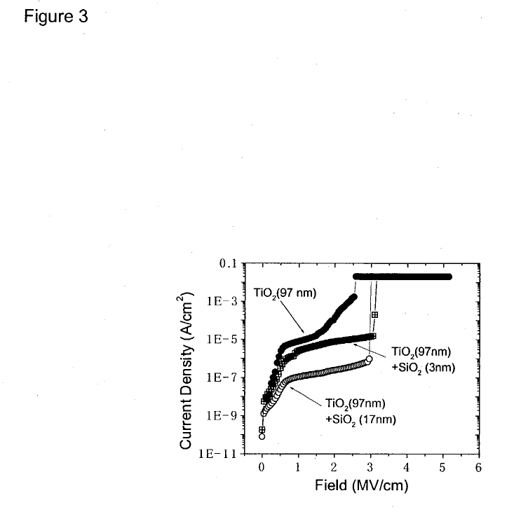

Thin SiO₂ layers were deposited onto the TiO₂ and Al₂O₃ films by plasma enhanced chemical vapor deposition, PECVD (under SiH₄ at flow rate of 100 sccm and N₂O at 300 sccm, at 250° C.). For this Example, SiO₂ thicknesses of 3 and 17 nm were deposited on top of the high dielectric constant films. FIG. 3 shows the leakage current as a function of the applied field and demonstrates that the leakage current decreases significantly after deposition of the thin SiO₂ layer onto the surface of the TiO₂ film. The breakdown field increases after deposition of the thin SiO₂ layer onto the surface of the TiO₂ film.

### EXAMPLE 2

### Effective Dielectric Constant of the Bilayer Gate Insulator

The capacitances of the TiO₂ film (d=97 nm) and the TiO₂ film with 3 and 17 nm thick SiO₂ overlayers were measured with the Hewlett-Packard 4155B semiconductor parameter analyser. With the channel length L equal to 5 micrometers and the channel width equal to 1000 micrometers, the measured capacitances were as follows: TiO₂ (97 nm thick): C=373 nF/cm²; TiO₂ (97 nm thick) with 3 nm SiO₂ overlayer: C=279 nF/cm²; TiO₂ (97 nm thick) with 17 nm SiO₂ overlayer: C=147 nF/cm². The corresponding values of the effective dielectric constant were as follows: TiO₂ (97 nm): k=41; TiO₂ (97 nm) with 3 nm SiO₂ overlayer: k=31; TiO₂ (97 nm) with 17 nm SiO₂ overlayer: k=19. The capacitances of the bilayer films are in good agreement with the formula for capacitors in series:

$$\frac{1}{{C}_{eff}} = \frac{1}{{C}_{T i {O}_{2}}} + \frac{1}{{C}_{S i {O}_{2}}} .$$

### EXAMPLE 3

### FETs with TiO₂ as the Gate Dielectric, without a Passivating Overlayer

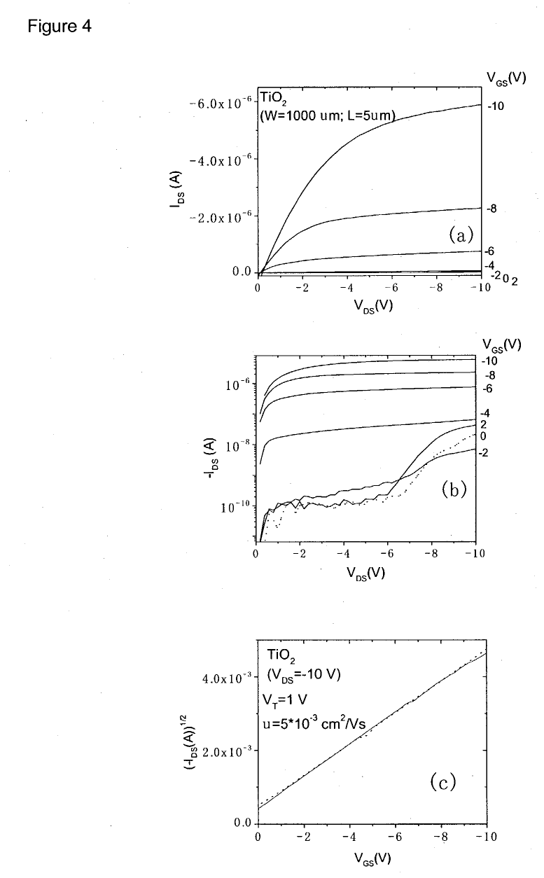

FIG. 4 shows source-drain current (I_{DS}) vs source-drain voltage (V_{DS}) at different gate voltages (V_{GS}) for RR-P3HT FETs with TiO₂ (thickness 97 nm, k=41) as gate insulator. FIG. 4(a) is a linear plot and shows good I-V characteristics for negative gate voltages (field induced holes) with saturation at voltages above 5 V. FIG. 4(b) is a semilog plot of I_{DS} vs V_{DS} at various V_{GS} for RR-P3HT FETs with TiO₂ (97 nm) as the gate dielectric. The carrier mobility was obtained from a linear plot of I_{DS}^{1/2} vs V_{GS} (FIG. 4c) using the following equation:

$${I}_{D S} = \frac{W {C}_{i}}{2 L} {μ ( {V}_{G S} - {V}_{T} )}^{2} .$$

where W is the channel width, L is the channel length, Cᵢ is the capacitance per unit area of the insulating layer, and V_{T} is the threshold voltage. With W=1000 μm, L=5 μm and Cᵢ=373 nF/cm², we obtain μ=5×10⁻³ cm²/Vs; i.e. reduced from that obtained with RR-P3HT with SiO₂ (200 nm thick) as the gate insulator by more than a factor of 20. The lower mobility implies increased disorder and surface roughness at the interface between the RR-P3HT and the TiO₂ gate insulator. Nevertheless, at V_{DS}=10 V and V_{GS}=−10 V, I_{DS}≈6 μA in FIG. 2b whereas for FETs fabricated in the same way with SiO₂ (200 nm) as the gate insulator, I_{DS}≈20 μA at V_{DS}=10 V and V_{GS}=−10 V (W=1000 μm, L=5 μm). Thus, as anticipated, the decrease in carrier mobility is partially compensated by the increased carrier density.

### EXAMPLE 4

### Atomic Force Microscopy Studies of the Gate Insulator Surface

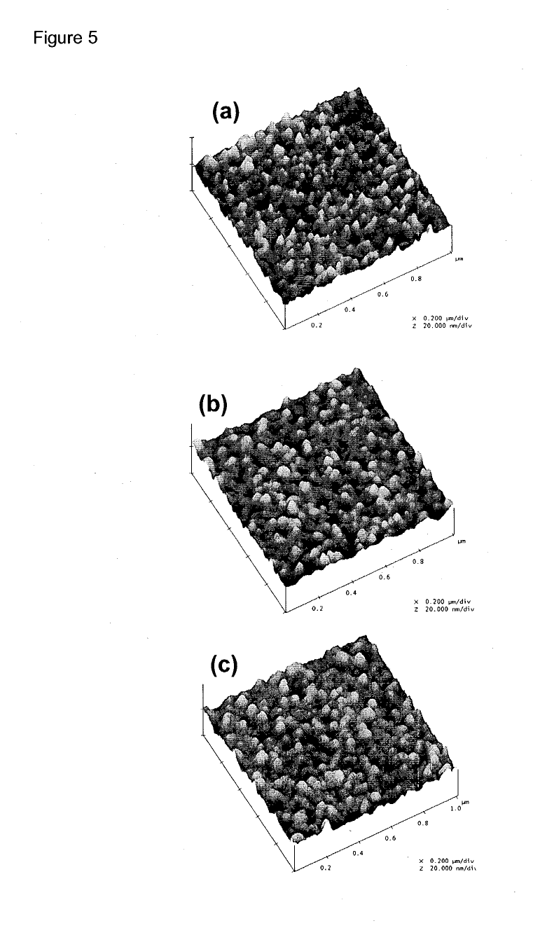

FIG. 5 shows atomic force micrograph (AFM) images of the surface of the (a) TiO₂ film and TiO₂ films with (b) a 3 nm thick SiO₂ overlayer and (c) a 17 nm thick SiO₂ overlayer. The surface features on the TiO₂ are sharper and their sizes are smaller than those on SiO₂/TiO₂ although the roughnesses (RMS) are similar, 1.533 nm for the TiO₂ film, 1.402 nm for SiO₂(3 nm)/TiO₂, and 1.538 nm for SiO₂(17 nm)/TiO₂. As noted above, such sharp features on the TiO₂ film will cause large variations in the local field. The blunted surface features on the SiO₂/TiO₂ films reduce such local field fluctuations and thereby improve the carrier transport in the channel.

### EXAMPLE 5

### FETs with Bilayer Gate Insulator

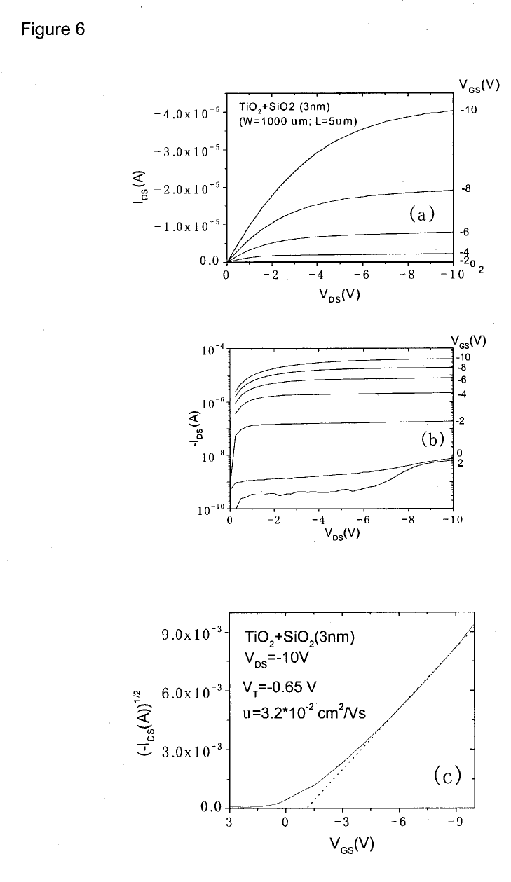

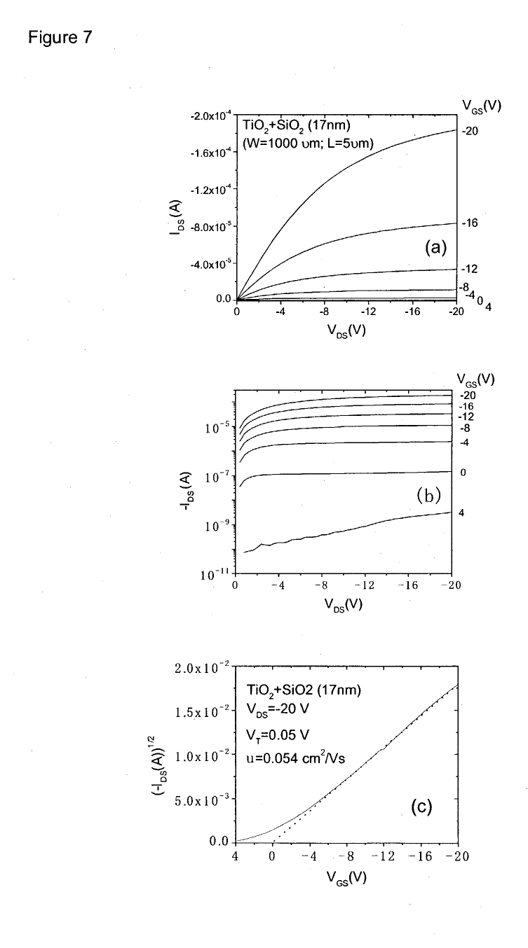

Linear plot and semilog plots of I_{DS} vs V_{DS} at different gate voltages and I_{DS}^{1/2} vs V_{GS} are shown respectively in FIGS. 6(a) and (b), and in FIGS. 7(a) and (b) for RR-P3HT FETs. The gate insulators comprise 97 nm TiO₂, with 3 nm and 17 nm thick SiO₂ overlayers respectively in FIGS. 6 and 7. The RR-P3HT films were applied by dip-coating from a solution of 1.0 mg/ml RR-P3HT in chloroform. Films were dip-coated at ˜0.2 mm/s. All solutions were filtered through a 0.20 μm pore size PTFE membrane syringe filter.

With TiO₂/SiO₂ (3 nm) as the gate insulator, I_{DS}≈−40 μA at V_{GS}=−10 V, compared to I_{DS}≈−6 μA without the SiO₂overlayer (see FIG. 4) and compared to I_{DS}≈20 μA at V_{DS}=10 V and V_{GS}=−10 V (for FETs fabricated in the same way with SiO₂ (200 nm) as the gate insulator). The leakage current is also lower; 1.9×10⁻⁷, 7.5×10⁻⁹, and 6.3×10⁻⁹ A at V_{GS} of −2, 0 and +2 V, respectively. Note also that the I_{DS} vs V_{DS} curves do not cross each other whereas they do cross in FIG. 4. With W=1000 μm, L=5 μm. Cᵢ=279 nF/cm², we obtain μ=3.2×10⁻² cm²/Vs from FIG. 6c; i.e. implying an increase in the mobility by a similar factor.

FIG. 7 shows that when the thickness of the silicon dioxide overlayer is increased to 17 nm, I_{DS}≈−30 μA at V_{DS}=−10 V and V_{GS}=−10 V; i.e. slightly lower than with the 3 nm SiO₂ overlayer even though the effective dielectric constant is reduced from 31 to 19, implying an increase in the mobility by a similar factor. Using equation 2 with W=1000 μm, L=5 μm. Cᵢ=147 nF/cm², we obtain μ=5.4×10⁻² cm²/Vs (compared with 3.2×10⁻² cm²/Vs for the 3 nm overlayer), within a factor of 2-4 of the best values obtained for RR-P3HT with SiO₂as the gate insulator [12,13]. In addition, the leakage current is still smaller and the on/off ratio is increased to approximately 6×10⁴.

The relatively high mobility obtained from RR-P3HT in FETs is ascribed to self-assembly and ordering of the polymer chains near the interface [H. Sirringhaus, P. J. Brown, R. H. Friend, M. M. Nielsen, K. Bechgaard, B. M. W. Langeveld-Voss, A. J. H. Spiering, R. A. J. Janssen, E. W. Meijer, P. Herwig, and D. M. de Leeuw, Nature 410 (1999) 685]. With dip coating, the film thickness is only 20˜40 Å [G. M. Wang, J. Swensen, D. Moses, A. J. Heeger, J. Appl. Phys. (In press)]. One should not be surprised, therefore, that the degree of structural order in such a thin film is affected by the detailed properties of the surface of the gate insulator. With a high dielectric constant gate insulator, surface roughness will cause strong variations in the local field with associated scattering of carriers and the possible formation of carrier traps. Although the addition of the thin SiO₂ overlayer reduces the effective dielectric constant, the overlayer passivates the TiO₂ surface and yields higher mobilities and higher on/off ratios.

1. In a field effect transistor having a gate, a gate insulator on the gate, a semiconducting polymer on the gate insulator, and source and drain contacts defining a carrier channel, the improvement according to which the gate insulator comprises a bilayer formed of a layer of high dielectric constant insulator and a thin layer of a low dielectric constant insulator serving to passivate the high dielectric constant insulator, the low dielectric constant insulator in contact with and between the layer of high dielectric constant insulator and the semiconducting polymer whereby to provide the channel with a higher density of carriers and a higher carrier mobility.

2. The improvement of claim 1 in which the semiconducting polymer has low carrier mobility when cast onto and in direct contact with the high dielectric constant insulator, the passivating layer providing the carriers induced in the channel with high carrier mobility.

3. The improvement of claim 1 in which the passivating layer is SiO₂.

4. The improvement of claim 1 in which the high dielectric constant insulator layer is Al₂O₃ or TiO₂.

5. The improvement of claim 1 in which the high dielectric constant insulator is a material with dielectric constant greater than 40.

6. The improvement of claim 1 in which the semiconducting polymer is selected from the group consisting of derivatives of polythiophene, poly(phenylene vinylene) and polyfluorene.

7. The improvement of claim 1 in which the semiconducting polymer is regio-regular poly(3-hexylthiophene) or poly(9,9-dioctylfluorene-co-bithiophene).

8. The improvement of claim 7 in which the semiconducting polymer is regio-regular poly(3-hexylthiophene).

9. The improvement of claim 1 in which the gate is formed of a material selected from the group consisting of metal, conductively doped silicon and conducting polymer.

10. The improvement of claim 1 having a top contact structure in which the source and drain contacts are separated from the gate insulator by the semiconducting polymer.

11. The improvement of claim 1 having a bottom contact structure in which the source and drain contacts are connected directly to the gate insulator.

12. A field effect transistor comprising:
a substrate;
a gate on the substrate;
a layer of high dielectric constant insulator on the gate;
a semiconducting polymer on the gate insulator;
source and drain contacts defining a carrier channel; and
a thin layer of low dielectric constant insulator serving to passivate the high dielectric constant insulator, the low dielectric constant insulator in contact with and between the layer of high dielectric constant insulator and the semiconducting polymer whereby to provide the channel with a higher density of carriers and a higher carrier mobility.

13. The improvement of claim 12 in which the passivating layer is SiO₂.

14. The improvement of claim 12 in which the high dielectric constant gate insulator layer is Al₂O₃ and/or TiO₂.

15. The improvement of claim 12 in which the high dielectric constant insulator is a material with dielectric constant greater than 40.

16. The improvement of claim 12 in which the semiconducting polymer is selected from the group consisting of derivatives of polythiophene, poly(phenylene vinylene) and polyfluorene.

17. The improvement of claim 12 in which the semiconducting polymer is regio-regular poly(3-hexylthiophene) or poly(9,9-dioctylfluorene-co-bithiophene).

18. The improvement of claim 17 in which the semiconducting polymer is regio-regular poly(3-hexylthiophene).

19. The improvement of claim 12 in which the gate is formed of a material selected from the group consisting of metal, conductively doped silicon and conducting polymer.

20. The improvement of claim 12 having a top contact structure in which the source and drain contacts are separated from the gate insulator by the semiconducting polymer.

21. The improvement of claim 12 having a bottom contact structure in which the source and drain contacts are connected directly to the gate insulator.

22. A field effect transistor comprising:
a substrate;
a metal gate on the substrate;
a layer of high dielectric constant TiO₂ insulator on the gate;
a semiconducting polymer formed of regio-regular poly(3-hexylthiophene) on the gate insulator, said semiconducting polymer having low carrier mobility;
source and drain contacts defining a carrier channel; and
a passivating thin layer of low dielectric constant SiO₂ insulator in contact with and between the layer of high dielectric constant insulator and the semiconducting polymer whereby to provide the channel with a higher density of carriers and a higher carrier mobility.
